(19) United States
(12) Patent Application Publication
(10) Pub. No.: US 2005/0157767 A1
(43) Pub. Date: Jul. 21, 2005

(54) Semiconductor laser and manufacturing method therefor

(75) Inventor: Masanori Watanabe, Nara-shi (JP)

Correspondence Address: Barry E. Bretschneider;Morrison & Foerster LLP, Suite 300, 1650 Tysons Boulevard, McLean, VA, 22102, US

(73) Assignee: Sharp Kabushiki Kaisha, Osaka (JP)

(21) Appl. No.: 11/023,452

(22) Filed: Dec. 29, 2004

(30) Foreign Application Priority Data
Jan. 16, 2004 (JP) 2004-008875

(51) Int. Cl. H01S 5/00

(52) U.S. Cl. 372/43

(57) ABSTRACT

A semiconductor laser has a ridge stripe region 150 with laminated structure 170 and first and second stripe-side regions 151, 152. The ridge stripe region 150 on a semiconductor substrate has a lower cladding layer, active layer, and upper cladding area. The first stripe side regions 151 are disposed on both outer sides of a ridge stripe region 150. The second stripe-side regions are disposed on both outer sides of the first stripe-side regions 151. A thickness from a lower surface of the upper cladding region to a lower surface of a buried layer 115 in the second stripe-side region is smaller than that in the first stripe-side region. A width of the first stripe side region 151 is larger in a middle portion of an oscillator than in a light emitting edge.

### RELATED APPLICATION

This application is based on Japanese Patent Application No. 2004-8875, the contents in which are incorporated herein by reference.

### BACKGROUND OF THE INVENTION

The present invention relates to a semiconductor laser and a manufacturing method therefor, and more particularly relates to a semiconductor laser and a manufacturing method therefor suitable for data write onto optical disks and data read from optical disks (hereinbelow referred to as “for optical disks”).

Conventionally, as semiconductor lasers in use for optical disks, the semiconductor lasers which emit laser light from their edges have been used. The semiconductor lasers for optical disks require laser light capable of offering a spot shape which is as close to a perfect circle as possible on an optical disk. Typically, the laser light has an elliptic cross section, and its aspect ratio of beam divergence is defined as θv/θh wherein θh represents a full-width at half maximum of horizontal beam divergence and θv represents a full-width at half maximum of vertical beam divergence. In order to obtain laser light having a cross section of a perfect circle shape, there are adopted a method for forming elliptic laser light into the perfect circle shape by a shaping means, and a method for forming laser light into the perfect circle shape by removing part of the periphery of the elliptic laser light. However, the former method entails a problem that introducing the shaping means increases manufacturing costs of semiconductor lasers. The latter method entails a problem that efficiency of the laser light is degraded and thereby an available laser light output is reduced.

When emitted laser light is high-powered for achieving high-speed data write onto optical disks, current-optical output characteristics of semiconductor lasers suffer nonlinearity called kink. The kink is generated due to generation of higher-order guide transverse modes other than a fundamental transverse mode when refractive index difference ΔN between inside and outside of a waveguide of a semiconductor laser is large with respect to a waveguide width W. As the optical output becomes larger, the refractive index difference ΔN is increased by heat generated inside the waveguide, resulting in generation of the kink.

Although the kink can be reduced by decreasing the refractive index difference ΔN, decrease in the refractive index difference ΔN causes decrease of the horizontal beam divergence θh. Normally, the horizontal beam divergence θh of emitted light is smaller than the vertical beam divergence θv of emitted light. Therefore, if the refractive index difference ΔN is decreased, the aspect ratio θv/θh becomes larger than 1. Further, if the refractive index difference ΔN is decreased, the light becomes highly susceptible to an influence of the increase in refractive index difference ΔN caused by enhancement of an optical output, which increases changes of the horizontal beam divergence θh with respect to changes in optical output. Difference equal to or more than 2° between the horizontal beam divergence θh during low output operation necessary for data read from the optical disk and that during high output operation necessary for data write onto the optical disk makes it unable to use a single optical pickup unit for both data writing and reading.

Japan Patent Application Laid-open Publication 10-144991 disclose a semiconductor laser structure embodying a method for increasing the horizontal beam divergence θh. FIG. 12 shows a top view of a semiconductor laser 21 according to Japan Patent Application Laid-open Publication 10-144991. The semiconductor laser 21 has a stripe-shaped waveguide 19. The width of the waveguide or a stripe width W is a constant width Wₛ₂ in the inside portion, though the width W is gradually narrowed from the width Wₛ₂ to a width Wₛ₁ in the vicinity of a light emitting edge. According to Japan Patent Application Laid-open Publication 10-144991, the taper-shaped stripe structure or edge width narrowing structure makes it possible to set the horizontal beam divergence θh at 8 to 15° while setting the refractive index difference ΔN in the inside portion at around 5×10⁻⁴, thereby allowing the aspect ratio to approximate to 1.

Japan Patent Application Laid-open Publication 10-144991 relates to a semiconductor laser for reading operation of optical disks such as DVDs with an optical output of several mW. Such structure substantially can not be applied to a semiconductor laser having an output as high as tens of mW necessary for high-speed write to optical disks. This is because high-output semiconductor lasers are incomplete without solution to the kink. FIG. 13 shows a relation between the stripe width W and the horizontal beam divergence θh. As it is clear from FIG. 13, in the case where the inner stripe width W is relatively large, the horizontal beam divergence θh tends to decrease as the stripe width W increases, and therefore decreasing a ridge width in the vicinity of the light emitting edge allows the horizontal beam divergence θh to become larger. However, the inner stripe width W of the semiconductor laser with consideration given to solution to the kink is in the range from the vicinity of a maximum value of the horizontal beam divergence θh to the region where the horizontal radiation beam divergence θh tends to increase as the stripe width W increases. Therefore even if the stripe width is decreased in the vicinity of the light emitting edge, the horizontal beam divergence θh does not become larger and rather becomes smaller.

Japan Patent Application Laid-open Publication 2-178986 relates to a semiconductor laser for read operation of CDs with an optical output of several mW. FIG. 14A is a top view of the semiconductor laser, in which a lower edge functions as a light emitting edges. FIG. 14B is a cross sectional view taken along a line b-b showing the inside of the semiconductor laser, and FIG. 14C is a cross sectional view taken along a line c-c showing the vicinity of the light emitting edge. As shown in FIG. 14A, not only a stripe width is set to be W₁ in the inside portion and is widened to W₂ in the range of distance “r” in the vicinity of the light emitting edge, but also the cross sectional structure of the laser is changed as shown in FIGS. 14B and 14C. The semiconductor laser is provided with an n-GaAs substrate 1, an n-GaAs buffer layer 2, an n-AlGaAs lower cladding layer 3, an AlGaAs lower light guide layer 4, an AlGaAs single quantum well active layer 5, an AlGaAs upper light guide layer 6, a p-AlGaAs upper cladding layer 7, a p-GaAs cap layer 8, a SiNₓ insulating film 9, a p-electrode 10 and an n-electrode 11. Reference numerals d₁, d₂ in FIGS. 14A and 14B denote a distance from a center of the active layer 5 to an upper surface of the upper cladding layer 7. These distances correspond to thicknesses of the sides of a ridge stripe region. By setting the distance d₂ in the vicinity of the light emitting edge portion shown in FIG. 14C smaller than the distance d₁ of the inside portion shown in FIG. 14B, i.e., by setting the thickness of the sides of the ridge-stripe region smaller in the inside portion than in the vicinity of the light emitting edge, the refractive index difference ΔN on the light emitting edge is increased. However, rapid increase in the refractive index at a boundary between the vicinity of the light emitting edge and the inside portion causes mode conversion loss of a guided wave, thereby making the structure unsuitable for high-output operation.

### SUMMARY OF THE INVENTION

An object of the present invention is to provide a semiconductor laser which is capable of emitting laser light with low aspect ratio without generating kink even during high-output operation, little power dependency of an horizontal beam divergence θh between a low-output operation and a high-output operation, low loss so as to allow the high-output operation, capable of offering a horizontal radiation light distribution close to Gaussian distribution, and excellent efficiency in use for optical disks, and a manufacturing method therefor.

The present invention provides a semiconductor laser, comprising, a ridge stripe region having a laminated structure provided with at least a lower cladding layer, an active layer, and an upper cladding layer, and formed on a semiconductor substrate, a first stripe-side region disposed on both outer sides of a ridge stripe region, provide with a buried layer on the upper cladding layer, having a first thickness H₁ from a lower surface of the upper cladding layer to a lower surface of the buried layer, and having a width D larger in a middle portion of an oscillator than in a light emitting edge, and a second stripe-side region disposed on both outer sides of the first stripe-side region at least in a vicinity of the light emitting edge, provided with a buried layer on the upper cladding layer, and having a second thickness H₂ from the lower surface of the upper cladding layer to the lower surface of the buried layer, the second thickness H₂ being smaller than the first thickness H₁.

FIG. 8 is a schematic perspective view for explaining the operation in this structure. Rapid change of the refractive index difference ΔN in a wave guide in a light emitting portion generates mode conversion loss. It is difficult in manufacturing process to gradually change the thickness of a section from the upper cladding layer to the lower surface of the buried layer on both sides of the ridge stripe region. However, in the present invention, a region (first stripe-side region) in which a remaining thickness or a thickness of the upper cladding layer is H₁ (first thickness) and a region (second stripe-side region) in which the thickness is H₂ (second thickness) are provided, and the width D of the region having the thickness of H₁ in the vicinity of the ridge stripe region is decreased toward the light emitting portion. This achieves that an effective refractive index difference ΔN is gradually changed (the refractive index difference ΔN is gradually increased from the inside portion of an oscillator to the light emitting portion), resulting in reduction of light loss by gradually narrowing distribution of a guided wave.

The increase of the horizontal beam divergence θh and the decrease of the aspect ratio θv/θh by increasing the refractive index difference ΔN in the light emitting portion will be described with reference to FIG. 9. In the case where a stripe width is smaller than a certain level, increasing the refractive index difference ΔN while keeping the stripe width constant is effective to increase the horizontal beam divergence θh. In order to change the refractive index difference ΔN in the inside portion of the oscillator and in the light emitting portion by equal to or more than 0.0001 to change the horizontal beam divergence θh by equal to or more than 0.1, the thickness H₂ should preferably be smaller than the thickness H₁ by equal to or more than 0.003 μm. Further, it is more preferable that the thickness H₁ is larger than the thickness H₂ by equal to or more than 0.017 μm because the refractive index difference ΔN is increased on the light emitting edge by equal to or more than 0.0005, and the horizontal beam divergence θh is increased by equal to or more than 0.5 degree. Furthermore, it is more preferable that the thickness H₁ is larger than the thickness H₂ by equal to or more than 0.034 μm because the refractive index difference ΔN is increased on the light emitting edge by equal to or more than 0.001, and the horizontal beam divergence θh is increased by equal to or more than 1 degree.

The width D in the first strip-side region on the light emitting edge is preferably equal to or more than 0.1 μm and equal to or less than 5 μm. FIG. 10 shows an example of a calculated value regarding a relation between the width D and the horizontal beam divergence θh. The more the width D increases, the more the horizontal beam divergence θh decreases. When the width D reaches equal to or more than 5 μm, the angle of radiation θh becomes almost constant, which indicates that the width D needs to be smaller than 5 μm on the light emitting edge. For setting the change amount of the horizontal beam divergence θh at equal to or less than 1°, the width D on the light emitting edge should be equal to or less than 2 μm. It is more preferable that the width D is equal to or more than 1 μm, because the change amount of the horizontal beam divergence θh becomes equal to or more than 2°.

As shown in FIG. 11, by providing the second stripe-side regions on the outer sides of the first stripe-side region on the light emitting edge so as to increase the refractive index difference ΔN in a bottom portion of the horizontal guided wave distribution, it becomes possible to cut a tail of the guided wave that adds the tail of the horizontal radiation on the Gaussian distribution resulting in that the distribution of the horizontal radiation light approximates to the Gaussian distribution. Since the tail of the horizontal radiation is not used for optical disks, reduction of such unavailable light increases the available light amount. For this purpose, the width D is preferably equal to or more than 1 μm. The width of the ridge stripe region in which primary parts of a guided wave exists is preferably constant from the inside portion to the light emitting edges since a loss caused due to change in the width can be almost eliminated.

In the vicinity of the light emitting edge, there is formed a window region where crystals of the active layer including a quantum well is intermixed. This makes it possible to suppress the deterioration of the light emitting edge during high-output operation.

Further, in the case where the lower cladding layer, the active layer, and the upper cladding layer are formed from (AlₓGa₁₋ₓ)_{y}In_{1-y}P (0≦x≦1, 0≦y≦1), it becomes possible to obtain a high-output semiconductor laser having an oscillation wavelength suitable for use in DVDs.

The upper cladding layer of the laminated structure may consist of first and second cladding layers with an etching stop layer interposed therebetween. In the first stripe-side region in the middle portion of the oscillator, the second upper cladding layer may have a thickness equal to or more than 0.003 μm (preferably equal to or more than 0.017 μm). In the second stripe-side region in the vicinity of the light emitting edge, the second upper cladding layer may be completely removed. The thickness H₁ of the upper cladding layer in the first stripe-side region influences the kink but does not directly influence the horizontal beam divergence θh. Therefore, according to the structure, the etching stop layer is used only with respect to the light emitting portion which influences the horizontal beam divergence θh, by which dispersion in the horizontal beam divergence θh can be suppressed.

Alternatively, the upper cladding layer of the laminated structure may consist of first and second cladding layers with an etching stop layer interposed therebetween. In the first stripe-side region in the middle portion of the oscillator, the second upper cladding layer may be removed up to the etching stop layer. In the second stripe-side region in the vicinity of the light emitting edge, the etching stop layer and part or all of the first upper cladding layer may be removed.

In this case, it is preferable that the window region is formed in the vicinity of the light emitting edge where the active layer including a quantum well and the etching stop layers are intermixed, and that in the second stripe-side region, the etching stop layer formed from intermixed crystals in the window region is removed. This allows the etching stop layer on the light emitting edge to be etched away by a single etching operation, and allows the thickness H₂ from the lower surface of the upper cladding layer to the lower surface of the buried layer in the second stripe-side region to be smaller than the thickness H₁ from the lower surface of the upper cladding layer to the lower surface of the buried layer in the first stripe-side region.

The upper cladding layer of the laminated structure may consist of first, second, and third upper cladding layers with first and second etching stop layers interposed therebetween. In the first stripe-side region in the middle portion of the oscillator, the third upper cladding layer may be removed up to the second etching stop layer. In the second stripe-side region in the vicinity of the light emitting edge, the third upper cladding layer, the second etching stop layer, and the second upper cladding layer may be removed. Providing such two etching stop layers allows strict control of both the thickness H₁ and H₂, thereby making it possible to ensure suppression of the kink and to reduce dispersion of the horizontal beam divergence θh.

In this case, it is preferable that the window region is formed in the vicinity of the light emitting edge where the active layer including a quantum well, the first etching stop layer and the second etching stop layers are intermixed, and that the second etching stop layer formed from intermixed crystals in the window region is removed. This allows the second etching stop layer on the light emitting end surface to be etched away by a single etching operation, and allows strict control of the remaining thickness H₂ of the upper cladding layer in the second stripe-side region as well as strict control of the horizontal beam divergence θh.

Further, in this case, it is preferable that the window region is formed in the vicinity of the light emitting edge where the active layer including a quantum well, the first etching layer, and the second etching layer are intermixed, and that a thickness of the first etching stop layer is larger than that of the second etching stop layer. More specifically, the first etching stop layer is defined to be significantly thicker by equal to or more than 0.001 μm. The first etching stop layer is preferably thicker by equal to or more than 0.002 μm, and more preferably be thicker by equal to or more than 0.003 μm. The second etching stop layer is an etching stop layer in the region where a window works as not formed. The first etching stop layer needs to have an effect as the etching stop layer in the region where a window is formed in the light emitting edge. Crystals of the first etching stop layer are intermixed with the first cladding layer and the second cladding layer along with formation of the window, and this weakens the function of the etching stop layer of the first etching stop layer. Forming the first etching stop layer thicker than the second etching stop layer makes it possible to reinforce the etching stop effect of the first etching stop layer which is weakened by the formation of the window.

In the present invention, there is provided a method for manufacturing a semiconductor laser, forming the lower cladding layer, the active layer, the first upper cladding layer, the etching stop layer and the second upper cladding layer in this order on the semiconductor substrate to provide the laminated structure, forming the first stripe-side region by etching the laminated structure on both outer sides of the stripe region so as to leave the second upper cladding layer with a thickness equal to or more than 0.003 μm, and forming the second stripe-side region by etching the second upper cladding layer up to the etching stop layer in the vicinity of the light emitting end surface. In the manufacturing method, the layer thickness is controlled by use of the etching stop layer in the light emitting portion, so that a beam divergence is determined with high accuracy. The accuracy of the thickness H₁ of the upper cladding layer is slightly lower in the inside portion than in the light emitting portion, though this will not affect the beam divergence.

Further in the present invention, there is provided a method for manufacturing a semiconductor laser comprising, forming the lower cladding layer, a lower guide layer, the active layer, an upper guide layer, the first upper cladding layer, the etching stop layer, and the second upper cladding layer in this order on the semiconductor substrate to provide the laminated structure, forming the first stripe-side region by etching the upper cladding layer of the laminated structure up to the etching stop layer on both outer sides of the stripe region, and forming the second stripe-side region by partially or completely etching the first upper cladding layer in the vicinity of the light emitting edge.

Furthermore in the present invention, there is provided a method for manufacturing the semiconductor laser comprising, forming the lower cladding layer, a lower guide layer, the active layer, an upper guide layer, the first upper cladding layer, the first etching stop layer, the second upper cladding layer with a thickness equal to or more than 0.003 μm, the second etching stop layer, and the third upper cladding layer in this order on the semiconductor substrate to provide the laminated structure, forming the first stripe-side region by etching the third upper cladding layer of the laminated structure up to the second etching stop layer on both outer sides of the stripe region, and forming the second stripe-side region by etching the second upper cladding layer of the laminated structure up to the first etching stop layer in the vicinity of the light emitting edge. A preferable thickness of the second upper cladding layer is equal to or more than 0.003 μm, and a more preferable thickness is equal to or more than 0.017 μm.

In the present invention, it is possible to provide a semiconductor laser which is capable of emitting laser light with low aspect ratio without generating kink even during high-output operation, little power dependency on the horizontal beam divergence between low-output operation and high-output operation, low loss, and is capable of offering horizontal beam distribution close to Gaussian distribution. Therefore, the semiconductor laser of the present invention is superior in efficiency in use for optical disks. Specifically, the semiconductor laser of the present invention makes it possible to provide an optical disk pickup unit with simple structure without degrading efficiency of laser light, thereby allowing decrease in size and weight of the optical pickup unit and high-speed access.

### BRIEF DESCRIPTION OF THE DRAWINGS

These and other objects and features of the invention will become apparent from the following description taken in conjunction with preferred embodiments of the invention with reference to the accompanying drawings, in which:

FIG. 1 is a top view showing a semiconductor laser according to a first embodiment of the present invention;

FIG. 2 is a cross sectional view taken along line II-II (direction vertical to a ridge stripe) of FIG. 1;

FIG. 3 is a diagram showing a relation between a stripe width and a refractive index difference for explaining the king suppression principle in the semiconductor laser according to the first embodiment of the present invention;

FIG. 4 is a top view showing a semiconductor laser according to a second embodiment of the present invention;

FIG. 5 is a cross sectional view taken along line V-V (direction vertical to a ridge stripe) of FIG. 4;

FIG. 6 is a top view showing a semiconductor laser according to a third embodiment of the present invention;

FIG. 7 is a cross sectional view taken along line VII-VII (direction vertical to a ridge stripe) of FIG. 6;

FIG. 8 is a schematic perspective view showing the operation principle of the semiconductor laser of the present invention;

FIG. 9 is a diagram view showing a relation between a stripe width and horizontal beam divergence for explaining the operation principle of the semiconductor laser of the present invention;

FIG. 10 is a diagram view showing a relation between a width of a first ridge-stripe region and a horizontal beam divergence for explaining the operation principle of the semiconductor laser of the present invention;

FIG. 11 is an explanatory view showing the shape of horizontal beam distribution in the semiconductor laser of the present invention;

FIG. 12 is a schematic top view showing one example of a conventional semiconductor laser;

FIG. 13 is an explanatory view showing the function of the conventional semiconductor laser shown in FIG. 12;

FIG. 14A is a top view showing another example of a conventional semiconductor laser;

FIG. 14B is a cross sectional view taken along line b-b of FIG. 14A; and

FIG. 14C is a cross sectional view taken along line c-c of FIG. 14A.

### DETAILED DESCRIPTION OF THE PREFERRED EMBODIMENTS

Embodiments of the present invention will be described hereinbelow. It is to be noted that throughout the accompanying drawings, same component members or corresponding component members are designated by same reference numerals. Further, in the specification, (AlₓGa₁₋ₓ)_{y}In_{1-y}P (provided that 0≦x≦1 and 0≦y≦1) may be abbreviated to AlGaInP, Ga_{z}In_{1-z}P (provided that 0≦z≦1) may be abbreviated to GaInP, and AlᵣGa₁₋ᵣAs (provided that 0≦r≦1) may be abbreviated to AlGaAs.

### First Embodiment

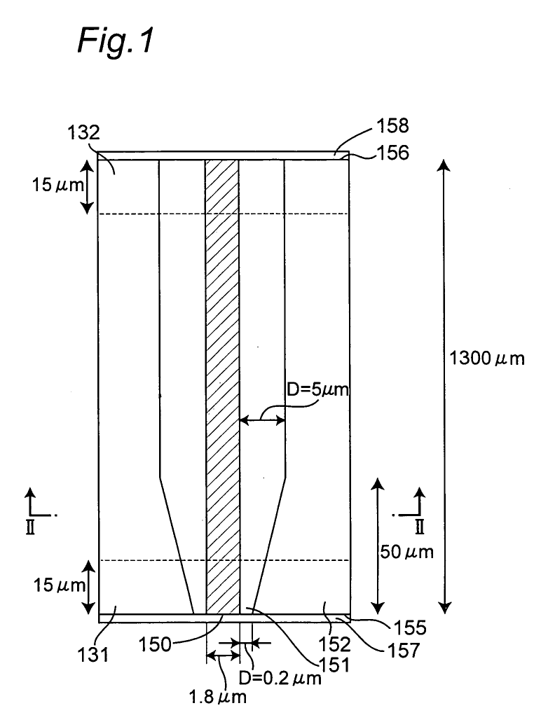

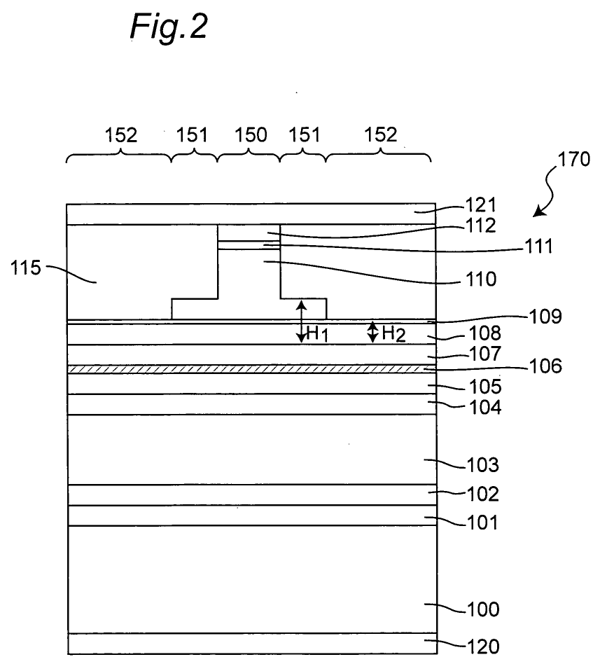

FIG. 1 is a schematic top view showing a preferred example of the present invention. As shown in FIGS. 1 and 2, a semiconductor laser of the present invention is provided with a laminated structure 170, a ridge stripe region 150, a first stripe-side region 151 and a second stripe-side region 152. The first stripe-side regions 151 are provided on both outer sides of the ridge stripe region 150, and the second stripe-side regions 152 are provided on both outer sides of the first stripe-side regions 151. The second stripe-side region 152 is extremely adjacent to the ridge stripe region 150 in the vicinity of a light emitting edge 155. Although a width D of the first stripe-side region is set at 0.2 μm in this example, it may be about 0.1 to 0.5 μm for example. The width D of the first stripe-side region 151 is gradually increased from the light emitting edge 155 to form a taper-shape, and becomes constant in the inside portion of an oscillator. The width D of the first stripe-side region 151 in the position 50 μm away from the light emitting front edge 155 is set at 5 μm. If the width is 5 μm or more, then the second stripe-side region 152 has substantially no influence on an effective refractive index difference ΔN. In the range of 15 μm from a light emitting front edge 155 and a light emitting rear edge 156, window regions 131, 132 are formed respectively.

FIG. 2 is a cross sectional view taken along a line II-II of the semiconductor laser shown in FIG. 1. According to the semiconductor laser of the present invention, a laminated structure 170 is formed on an n-type GaAs substrate 100 in the ridge stripe region 150, the first stripe-side region 151, and the second stripe-side region 152. More specifically, respective layers of the laminated structure 170 are sequentially formed on the n-type GaAs substrate 100. The laminated structure 170 includes, an n-type GaAs buffer layer 101, an n-type Ga_{0.5}In_{0.5}P buffer layer 102, an n-type (Al_{0.67}Ga_{0.33})_{0.5}In_{0.5}P first lower cladding layer 103 (with a thickness of 2.0 μm), an n-type (Al_{0.7}Ga_{0.3})_{0.5}In_{0.5}P second lower cladding layer 104 (with a thickness of 0.2 μm), an undoped (Al_{0.5}Ga_{0.5})_{0.5}In_{0.5}P lower guide layer 105 (with a thickness of 0.05 μm), an undoped active layer 106 including a quantum well, an undoped (Al_{0.5}Ga_{0.5})_{0.5}In_{0.5}P upper guide layer 107 (with a thickness of 0.05 μm), a p-type (Al_{0.7}Ga_{0.3})_{0.5}In_{0.5}P first upper cladding layer 108 (with a thickness of 0.19 μm), and a p-type Ga_{0.7}In_{0.3}P etching stop layer 109 (with a thickness of 0.01 μm).

A thickness (second thickness) H₂ from the lower surface of the upper cladding layer 108 to the upper surface of the etching stop layer 109 in the second stripe-side region 152, i.e., a thickness from the lower surface of the upper cladding layer 108 to a lower surface of a later-described buried layer 115 is 0.20 μm.

In the first stripe-side region 151, there is formed a p-type (Al_{0.7}Ga_{0.3})_{0.5}In_{0.5}P second upper cladding layer 110 (with a thickness of 0.11 μm) protruding upward from a part of the surface of the p-type Ga_{0.7}In_{0.3}P etching stop layer 109. A thickness (first thickness) H₁ from the lower surface of the upper cladding layer 108 to an upper surface of the second upper cladding layer 110 in the first stripe-side region 151, i.e., a thickness from the lower surface of the upper cladding layer 108 to the lower surface of the later-described buried layer 115 is 0.31 μm.

In the ridge stripe region 150, a p-type (Al_{0.7}Ga_{0.3})_{0.5}In_{0.5}P second upper cladding layer 110 (with a thickness of 0.12 μm) protruding upward from a part of the surface of the p-type Ga_{0.7}In_{0.3}P etching stop layer 109, a p-type Ga_{0.5}In_{0.5}P intermediate band gap layer 111 (with a thickness of 0.05 μm), and a p-type GaAs cap layer 112 (with a thickness of 0.5 μm) are formed in sequence.

A buried layer 115 made of SiO₂ is formed on the second upper cladding layer 110 in the first stripe-side region 151 and on the p-type etching stop layer 109 in the second stripe-side region 152. Further, a p-electrode 121 is formed on the buried layer 115 and the p-type GaAs layer 112. Furthermore, an n-electrode 120 is formed on the surface of the n-type GaAs substrate 100 opposite to the side on which the semiconductor layers are laminated.

As shown in FIG. 1, a front-face reflection coating 157 and a rear-face reflection coating 158 are formed respectively on the light emitting edges 155, 156 which are vertical to the surface of the n-type substrate 100.

The active layer 106 is herein structured from a Ga_{0.5}In_{0.5}P quantum well layer of 5 nm thick, (Al_{0.5}Ga_{0.5})_{0.5}In_{0.5}P barrier layer of 5 nm thick, Ga_{0.5}In_{0.5}P quantum well layer of 5 nm thick, (Al_{0.5}Ga_{0.5})_{0.5}In_{0.5}P barrier layer of 5 nm thick, and a Ga_{0.5}In_{0.5}P quantum well layer of 5 nm thick, which are laminated in this order from the side of the n-type second lower cladding layer 104.

Further, the n-electrode 120 is formed from an AuGe layer, an Ni layer, a Mo layer, and an Au layer which are laminated on the n-type substrate 100 in this order. The p-electrode 121 is formed from an AuZu layer, a Mo layer, and an Au layer which are laminated in this order on the p-type cap layer 112 and the buried layer 115.

Further, the front edge reflection coating 157 (reflectance of 8%) on the light emitting edge 155 is an Al₂O₃ layer, while the rear-face reflection coating 158 (reflectance of 90%) on the light emitting end surface 156 is formed from an Al₂O₃ layer, a Si layer, an Al₂O₃ layer, a Si layer, and an Al₂O₃ layer which are laminated in this order from the light emitting edge 156. It is to be noted that an oscillator length of the semiconductor laser is 1300 μm.

The semiconductor laser of the present invention is manufactured by the following process. First, the n-type GaAs buffer layer 101, n-type Ga_{0.5}In_{0.5}P buffer layer 102, n-type (Al_{0.67}Ga_{0.33})_{0.5}In_{0.5}P first lower cladding layer 103, n-type (Al_{0.7}Ga_{0.3})_{0.5}In_{0.5}P second lower cladding layer 104, undoped (Al_{0.5}Ga_{0.5})_{0.5}In_{0.5}P lower guide layer 105, undoped active layer 106 including the quantum well, undoped (Al_{0.5}Ga_{0.5})_{0.5}In_{0.5}P upper guide layer 107, p-type (Al_{0.7}Ga_{0.3})_{0.5}In_{0.5}P first upper cladding layer 108, p-type Ga_{0.7}In_{0.3}P etching stop layer 109, p-type (Al_{0.7}Ga_{0.3})_{0.5}In_{0.5}P second upper cladding layer 110, p-type Ga_{0.5}In_{0.5}P intermediate band gap layer 111, and p-type GaAs cap layer 112 are formed in sequence on the n-type GaAs substrate 100.

Then, a ZnO film and an SiO₂ film (either unshown) are formed and retained at a high temperature to form the window regions 131, 132. This leads the active layer 106 and the etching stop layer 109 in the window regions 131, 132 to be intermixed.

Then, an SiO₂ film (unshown) is formed on the ridge stripe region 150 by photo lithography, and the first and second stripe-side regions 151, 152 are etched by dry etching method (e.g., ICP (Inductive Coupled Plasma) method or RIBE (Reactive Ion Beam Etching) method) so that both of the first and second stripe-side regions 151, 152 have a thickness equal to that of the second upper cladding layer 110 (0.11 μm).

Then, the ridge stripe region 150 and the first stripe-side region 151 are covered with resist, and the region 152 is etched with a wet etchant (phosphoric acid or hydrochloric acid) which doesn't etch the etching stop layer 109. The buried layer 115 is formed on the entire surface, and the buried layer 115 on the ridge stripe region 150 other than the window regions 131, 132 is removed. After the electrodes 120, 121 are formed, a wafer is cleaved to obtain the light emitting edges 155, 156, each on which the reflection coatings 157, 158 are formed. It is to be noted that the buried layer 115 is formed on the p-type GaAs cap layer 112 in the window regions 131, 132 (not shown), which prevents reactive current from flowing in the window regions 131, 132.

In the typical semiconductor laser of the present invention, the optical output of pulsed operation is kink free up to 280 mW. A vertical beam divergence is 15° and a horizontal beam divergence is 12° (aspect ratio of 1.25) at the time of 3 mW CW output, and is 13° (aspect ratio of 1.15) at the time of 100 mW CW output. Thus, the aspect ratio becomes close to 1 as almost no power dependency is seen. This makes it possible to obtain a light spot close to a perfect circle on an optical disk without the necessity of shaping laser light. As for other characteristics, a oscillation wavelength is 658 nm, a threshold current is 45 mA, a characteristic temperature of the threshold current is 110K, derivative quantum efficiency is 1.1W/A, and long-term operation with an optical output of 200 mW (pulse width of 50 ns, duty of 50%) at 70° C. is achieved for more than 3000 hours.

For comparison, the vertical beam divergence, the horizontal beam divergence, and the aspect ratio were examined in a semiconductor laser with a structure similar to that of the semiconductor laser of the present invention except that the second stripe-side region 152 does not exist. As a result, the vertical beam divergence was 15°, the horizontal beam divergence was 7.5° (aspect ratio of 2.0) during low output of 3 mW and 10° during output of 100 mW CW (aspect ratio of 1.5), which indicated the presence of large power dependency of θh.

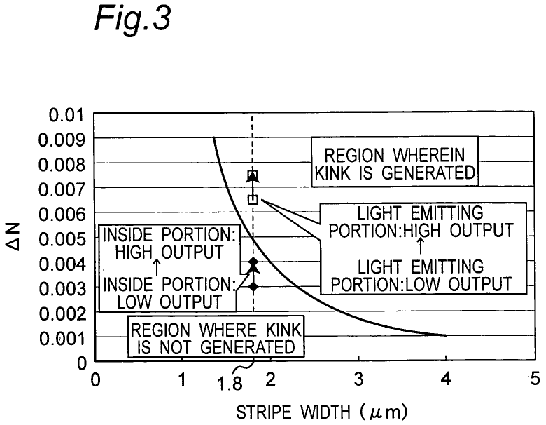

Description is given of this point with reference to FIG. 3 showing a relation between the stripe width and the refractive index difference ΔN. In the present embodiment, the refractive index difference ΔN in the inside portion is as small as 0.003, and therefore no kink is generated. However, this decreases the horizontal beam divergence θh, and as the output power increases, the refractive index difference ΔN increases, causing the rapid increase of the horizontal beam divergence θh. In the light emitting portion, the refractive index difference ΔN is extremely large. Consequently, the horizontal beam divergence θh is originally large, and therefore less susceptible to the change of output power. Of course, applying such a high refractive index difference ΔN to the entire laser wave guide causes generation of kink. In the present invention, however, it becomes possible to keep the refractive index difference ΔN in the region away from the laser light emitting portion at a value which does not generate the kink.

### Second Embodiment

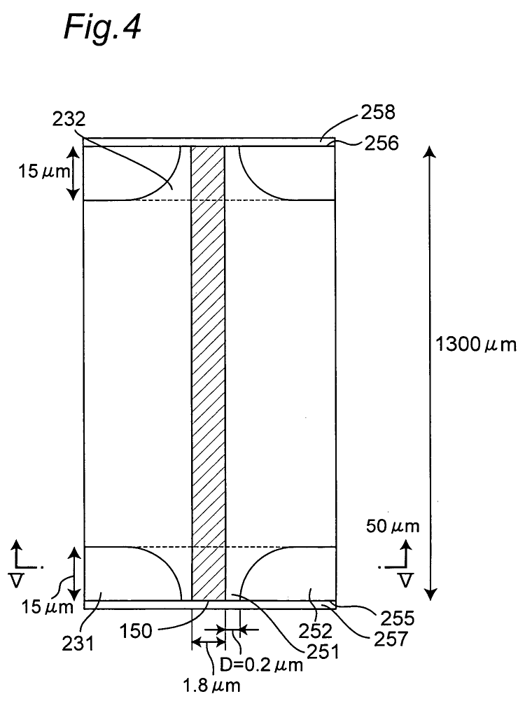

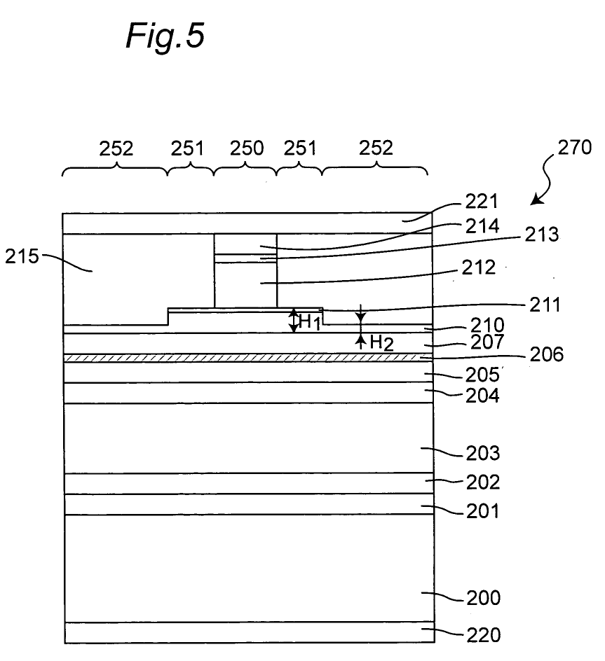

FIG. 4 is a schematic top view showing a second embodiment of the present invention. As shown in FIGS. 4 and 5, a second semiconductor laser is provided with a laminated structure 270, a ridge stripe region 250, a first stripe-side region 251, and a second stripe-side region 252. Further, in the range of 15 μm from a light emitting front edge 255 and a light emitting rear edge 256, window regions 231, 232 are formed respectively. The second stripe-side region 252 is extremely adjacent to the ridge stripe region 250 in the vicinity of the light emitting front edge 255, and a width D of the first strip-side region is about 0.3 μm herein. The width D of the first stripe-side region 251 is rapidly increased in the vicinity of the boundary of the window regions, and the second stripe-side region 252 is not present in the inner side of an oscillator from the window regions 231, 232.

FIG. 5 is a cross sectional view taken along the line V-V of the semiconductor laser shown in FIG. 4. According to the semiconductor laser of the present invention, in the ridge stripe region 250, first stripe-side region 251, and second stripe-side region 252, a laminated structure 270 is formed on an n-type GaAs substrate 200. More specifically, the laminated structure 270 includes an n-type GaAs buffer layer 201, an n-type Ga_{0.5}In_{0.5}P buffer layer 202, an n-type (Al_{0.67}Ga_{0.33})_{0.5}In_{0.5}P first lower cladding layer 203 (with a thickness of 2.0 μm), n-type (Al_{0.7}Ga_{0.3})_{0.5}In_{0.5}P second lower cladding layer 204 (with a thickness of 0.2 μm), undoped (Al_{0.5}Ga_{0.5})_{0.5}In_{0.5}P lower guide layer 205 (with a thickness of 0.05 μm), undoped active layer 206 including a quantum well, and undoped (Al_{0.5}Ga_{0.5})_{0.5}In_{0.5}P upper guide layer 207, which are sequentially formed on the n-type GaAs substrate 200.

A thickness H₂ of a p-type (Al_{0.7}Ga_{0.3})_{0.5}In_{0.5}P upper cladding layer 210 in the second stripe-side region 252 is 0.19 μm.

In the first stripe-side region 251, the p-type (Al_{0.7}Ga_{0.3})_{0.5}In_{0.5}P first upper cladding layer 210 (with a thickness of 0.27 μm) and a p-type Ga_{0.7}In_{0.3}P etching stop layer 211 (with a thickness of 0.01 μm) are formed. The thickness H₁ of the upper cladding layer in the first stripe-side region 251 is 0.28 μm.

In the ridge stripe region 250, a p-type (Al_{0.7}Ga_{0.3})_{0.5}In_{0.5}P second upper cladding layer 212 (with a thickness of 1.2 μm) protruding upward from a part of the surface of the p-type Ga_{0.7}In_{0.3}P etching stop layer 211, p-type Ga_{0.5}In_{0.5}P intermediate band gap layer 213 (with a thickness of 0.05 em), and p-type GaAs cap layer 214 (with a thickness of 0.5 μm) are formed in sequence.

Further, a buried layer 215 made of Si₃N₄ is formed on the p-type Ga_{0.7}In_{0.3}P etching stop layer 211 in the first stripe-side region 251 and on the first upper cladding layer 210 in the second stripe-side region 252, and a p-electrode 221 is formed on the buried layer 215 and the p-type GaAs layer 214. Further, an n-electrode 220 is formed on the surface of the n-type GaAs substrate 200 opposite to the side on which the semiconductor layers are laminated.

As shown in FIG. 4, a front-face reflection coating 257 and a rear-face reflection coating 258 are formed respectively on the light emitting edges 255, 256 which are vertical to the surface of the n-type substrate 200.

The active layer 206, n-electrode 220, p-electrode 221, front-face reflection coating 257, and the rear-face reflection coating 258 respectively have the same structures as those of the active layer 106, n-side electrode 120, p-side electrode 121, front-face reflection coating 157, and rear-face reflection coating 158.

The semiconductor laser of the present embodiment is manufactured in the following process. First, the n-type GaAs buffer layer 201, n-type Ga_{0.5}In_{0.5}P buffer layer 202, n-type (Al_{0.67}Ga_{0.33})_{0.5}In_{0.5}P first lower cladding layer 203, n-type (Al_{0.7}Ga_{0.3})_{0.5}In_{0.5}P second lower cladding layer 204, undoped (Al_{0.5}Ga_{0.5})_{0.5}In_{0.5}P lower guide layer 205, undoped active layer 206 including a quantum well, undoped (Al_{0.5}Ga_{0.5})_{0.5}In_{0.5}P upper guide layer 207, p-type (Al_{0.7}Ga_{0.3})_{0.5}In_{0.5}P first upper cladding layer 210, p-type Ga_{0.7}In_{0.3}P etching stop layer 211, p-type (Al_{0.7}Ga_{0.3})_{0.5}In_{0.5}P second upper cladding layer 212, p-type Ga_{0.5}In_{0.5}P intermediate band gap layer 213, and p-type GaAs cap layer 214 are formed in sequence on the n-type GaAs substrate 200.

Then, on regions 231 and 232 with a width of 15 μm from the light emitting edges 255, 256 on the forward and backward sides in FIG. 4, a ZnO film and an SiO₂ film (either not shown) are formed and retained at a high temperature to form the window regions 231, 232. This leads the active layer 206 and the etching stop layer 211 in the window regions 231, 232 to be intermixed.

Then, an SiO₂ film (not shown) is formed on the ridge stripe region 250 by photo lithography, and the first and second stripe-side regions 251, 252 are both etched by dry etching method so that the second upper cladding layer 212 slightly remains. Then, with a wet etchant (phosphoric acid or hydrochloric acid) which doesn't etch the etching stop layer, etching is continued to the etching stop layer 211. At this point, crystals of the etching stop layer 211 are intermixed with adjacent layers in the window regions 231, 232, which deteriorates a function of the etching stop layer, and in the vicinity of the window regions, a part of the first upper cladding layer 210 is etched away. Thus, in the window regions 231, 232, the structure of thin upper cladding layer H₂ is spontaneously obtained. After that, the buried layer 215 is formed on the entire surface, and the buried layer 215 on the ridge stripe region 250 other than the window regions 231, 232 is removed. After the electrodes 220, 221 are formed, a wafer is cleaved to obtain the light emitting edges 255, 256, each on which the reflection coatings 257, 258 are formed. It is to be noted that the buried layer 215 is formed on the p-type GaAs cap layer 212 in the window regions 231, 232 (not shown), which prevents non-effective current from flowing in the window regions.

The width of the first stripe-side region 251 is gradually changed from the light emitting edges toward the inside portion even without the use of resist because of the following reason. When the window regions 231, 232 are formed, a transition region from the window to the inside portion of approx. 20 μm-transition is generated. If the window length is 15 μm, it is smaller than its transition region width, and so the window effect is continuously increased toward the light emitting edge. As the window effect increases, the effect of the etching stop layer 211 decreases. Further, in the region adjacent to the ridge, flow of the etchant in wet etching is deteriorated and an etching rate is decreased. With combination of these two effects, a boundary between the second stripe-side region 252 and first stripe-side region 251, i.e., the width D of the region 251, gradually becomes larger from the light emitting portion toward the inside portion.

It is to be noted that in the second stripe-side region 252, the upper cladding layer 210 may be completely removed. In this case, since an Al composition of of the undoped (Al_{0.5}Ga_{0.5})_{0.5}In_{0.5}P upper guide layer 207 is set lower than that of the first cladding layer 210, the etching rate is considerably dropped at the upper guide layer 207. This results in that the upper guide layer 207 is hardly etched away and the thickness is stabilized.

Further, in the etching process of the upper cladding layer 210 on the second stripe-side region 252, the regions 251, 252 may be etched to the extent that the etching stop layer 211 is maintained. After that, the etching stop layer 211 and upper cladding layer 210 are etched by dry etching using a resist pattern with an aperture corresponding to the second stripe-side region 252. This allows to preferably control the remaining thickness H₂ of the upper cladding layer.

### Third Embodiment

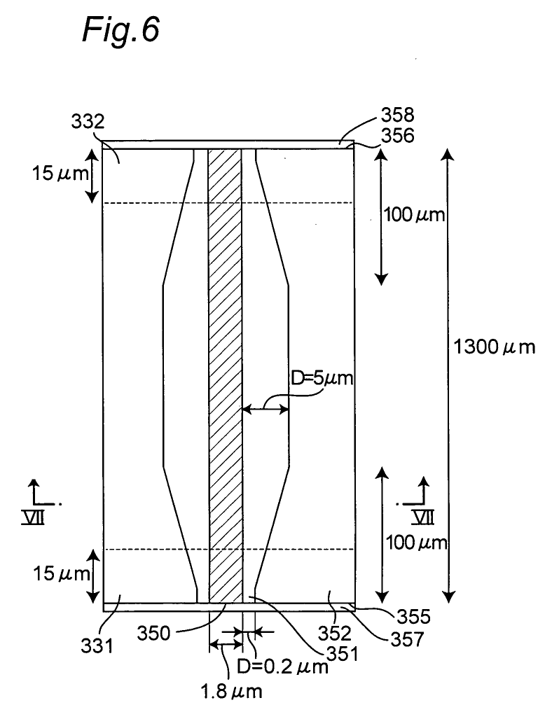

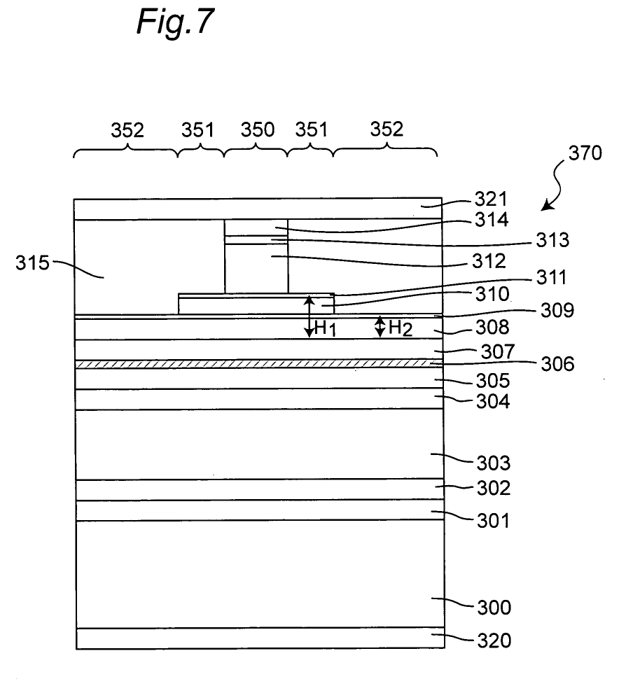

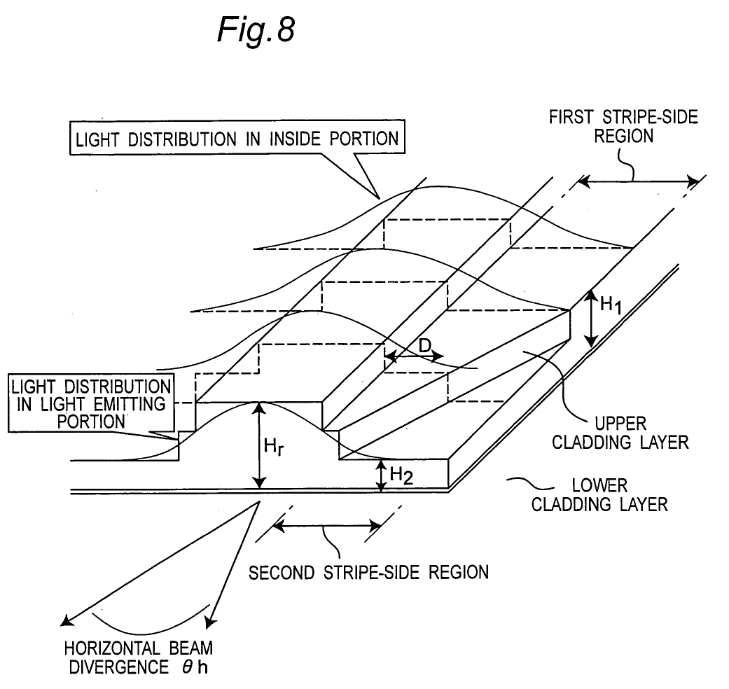

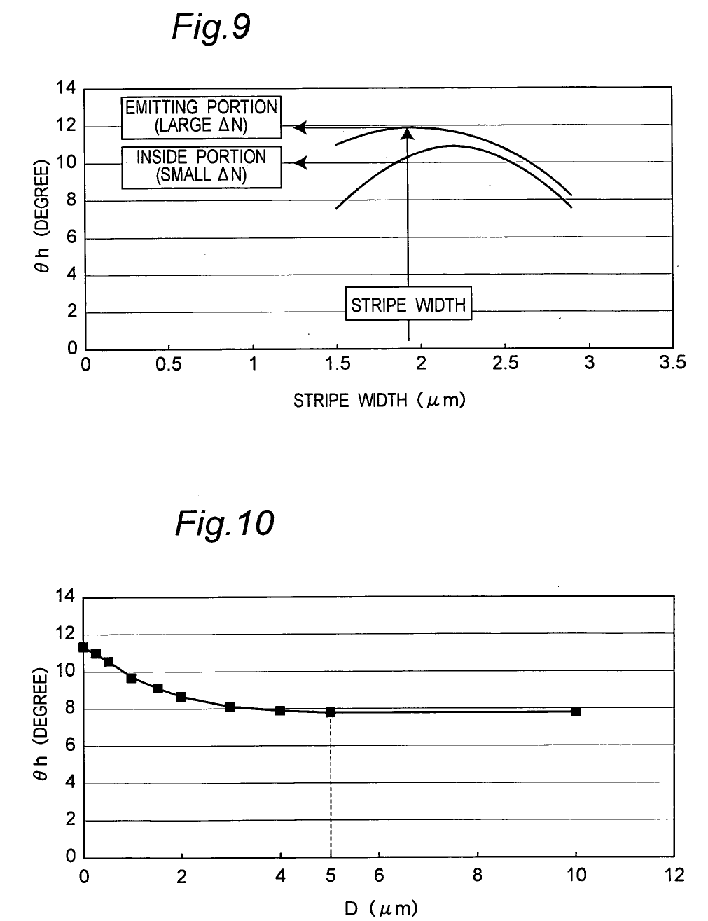

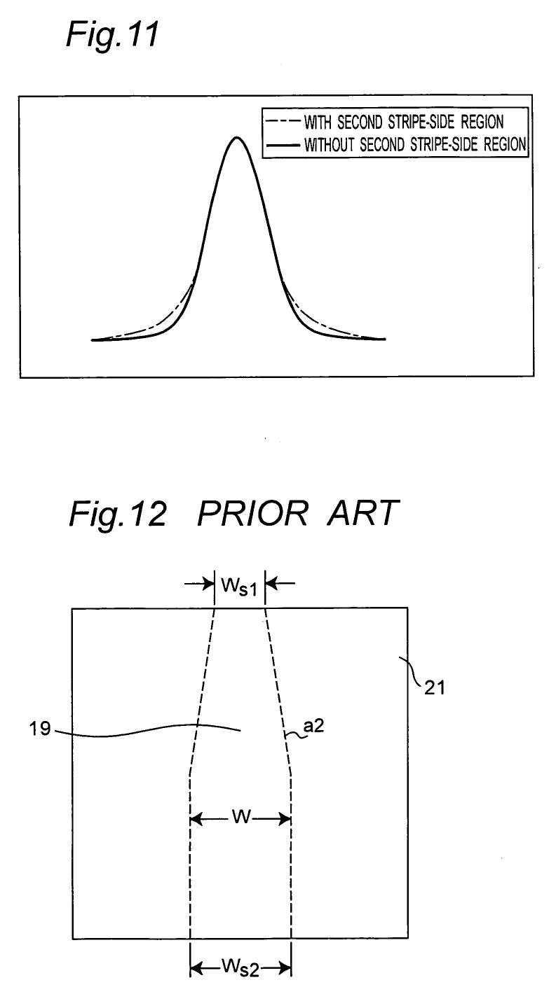

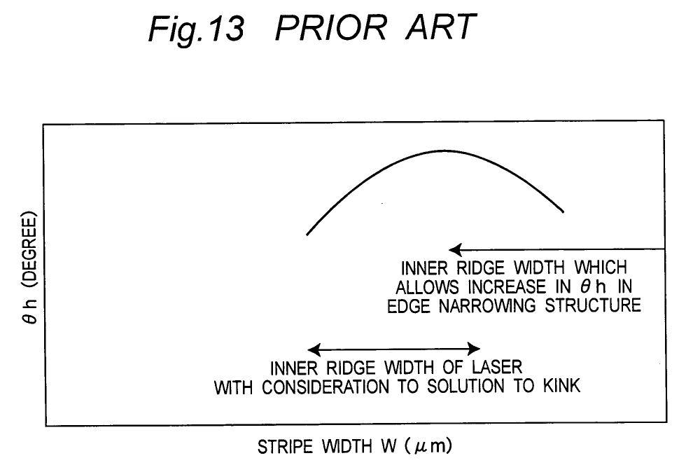

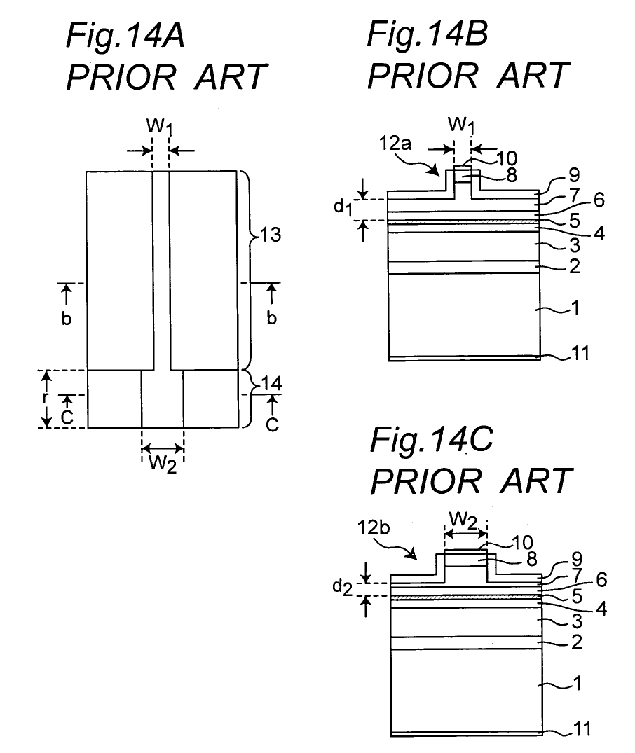

FIG. 6 is a schematic top view showing a third embodiment of the present invention. As shown in FIGS. 6 and 7, a semiconductor laser of the present embodiment is provided with a laminated structure 370, ridge stripe region 350, first stripe-side region 351, and a second stripe-side region 352. The second stripe-side region 352 is extremely adjacent to the ridge stripe region 350 in the vicinity of a light emitting edge 355, and the width D of the first strip-side region is herein set at about 0 to 0.5 μm, preferably about 0.05 to 0.2 μm. The width D of the first stripe-side region is gradually increased preferably from the light emitting edge 355, and becomes 5 μm in a position 100 μm away from oscillator edges. If the width is 5 μm or more, then the second stripe-side region 352 has substantially no influence on a guided wave. In the range of 15 μm from the light emitting front edge 355 and light emitting rear edge 356, window regions 331, 332 are respectively formed.

FIG. 7 is a cross sectional view taken along the line VII-VII of the semiconductor laser shown in FIG. 6. According to the semiconductor laser of the present embodiment, a laminated structure 370 is formed on an n-type GaAs substrate 300 in the ridge stripe region 350, first stripe-side region 351, and second stripe-side region 352. More specifically, the laminated structure 370 includes an n-type GaAs buffer layer 301, n-type Ga_{0.5}In_{0.5}P buffer layer 302, n-type (Al_{0.67}Ga_{0.33})_{0.5}In_{0.5}P first lower cladding layer 303 (with a thickness of 2.0 μm), n-type (Al_{0.7}Ga_{0.3})_{0.5}In_{0.5}P second lower cladding layer 304 (with a thickness of 0.2 μm), undoped (Al_{0.5}Ga_{0.5})_{0.5}In_{0.5}P lower guide layer 305 (with a thickness of 0.05 μm), undoped active layer 306 including a quantum well, undoped (Al_{0.5}Ga_{0.5})_{0.5}In_{0.5}P upper guide layer 307 (with a thickness of 0.19 μm), p-type (Al_{0.7}Ga_{0.3})_{0.5}In_{0.5}P first upper cladding layer 308, and p-type Ga_{0.7}In_{0.3}P first etching stop layer 309 (with a thickness of 0.015 μm), which are sequentially formed on the n-type GaAs substrate 300.

A thickness H₂ from the upper cladding layer to the first etching stop layer in the second stripe-side region 352 is 0.1915 μm.

In the first stripe-side region 351, p-type (Al_{0.7}Ga_{0.3})_{0.5}In_{0.5}P second upper cladding layer 310 (with a thickness of 0.11 μm) protruding upward from a part of the surface of the p-type Ga_{0.5}In_{0.3}P first etching stop layer 309, and p-type Ga_{0.7}In_{0.3}P second etching stop layer 311 (with a thickness of 0.11 μm) are formed. A thickness H₁ from the upper cladding layer to the second etching stop layer in the first stripe side region 351 is 0.3115 μm.

In the ridge stripe region 350, a p-type (Al_{0.7}Ga_{0.3})_{0.5}In_{0.5}P third upper cladding layer 312 (with a thickness of 1.2 μm) protruding upward from a part of the surface of the p-type Ga_{0.7}In_{0.3}P second etching stop layer 311, p-type Ga_{0.5}In_{0.5}P intermediate band gap layer 313 (with a thickness of 0.05 μm), and p-type GaAs cap layer 314 (with a thickness of 0.5 μm) are formed in sequence.

A buried layer 315 made of Si₃N₄ is formed on the p-type Ga_{0.7}In_{0.3}P second etching stop layer 311 in the first stripe-side region 351 and on the p-type Ga_{0.7}In_{0.3}P first etching stop layer 309 in the second stripe-side region 352. A p-electrode 321 is formed on the buried layer 315 and the p-type GaAs layer 314. Further, an n-electrode 320 is formed on the surface of the n-type substrate 300 opposite to the side on which the semiconductor layers are laminated.

As shown in FIG. 6, a front-face reflection coating 357 and a rear-face reflection coating 358 are formed respectively on the light emitting edges 355, 356 vertical to the surface of the n-type substrate 300.

The active layer 306, n-side electrode 320, p-side electrode 321, front-face reflection coating 357, and rear-face reflection coating 358 have respectively same structures as those of the active layer 106, n-side electrode 120, p-side electrode 121, front-face reflection coating 157, and rear-face reflection coating 158.

The semiconductor laser of the present embodiment is manufactured in the following process. First, the n-type GaAs buffer layer 301, n-type Ga_{0.5}In_{0.5}P buffer layer 302, n-type (Al_{0.67}Ga_{0.33})_{0.5}In_{0.5}P first lower cladding layer 303, n-type (Al_{0.7}Ga_{0.3})_{0.5}In_{0.5}P second lower cladding layer 304, undoped (Al_{0.5}Ga_{0.5})_{0.5}In_{0.5}P lower guide layer 305, undoped active layer 306 including a quantum well, undoped (Al_{0.5}Ga_{0.5})_{0.5}In_{0.5}P upper guide layer 307, p-type (Al_{0.7}Ga_{0.3})_{0.5}In_{0.5}P first upper cladding layer 308, p-type Ga_{0.7}In_{0.3}P first etching stop layer 309, p-type (Al_{0.7}Ga_{0.3})_{0.5}In_{0.5}P second upper cladding layer 310, p-type Ga_{0.7}In_{0.3}P second etching stop layer 311 (with a thickness of 0.01 μm), p-type (Al_{0.7}Ga_{0.3})_{0.5}In_{0.5}P third upper cladding layer 312, p-type Ga_{0.5}In_{0.5}P intermediate band gap layer 313, and p-type GaAs cap layer 314 are formed in sequence on the n-type GaAs substrate 300.

Then, on regions 331 and 332 with a width of 15 μm from the light emitting edges 355, 356 on the forward and backward sides in FIG. 6, a ZnO film and an SiO₂ film (either not shown) are formed and retained at a high temperature to form the window regions 331, 332. This leads the active layer 306 and the etching stop layers 309, 311 in the window regions 331, 332 to be intermixed.

After the ZnO film and the SiO₂ film are removed, an SiO₂ film (not shown) is formed on the upper portion of the ridge stripe region 350 by photo lithography, and the first and second stripe-side regions 351, 352 are both etched by dry etching method so that the third upper cladding layer 312 slightly remains. Then, with a wet etchant (phosphoric acid or hydrochloric acid), etching is continued to the second etching stop layer 311. Further, a resist pattern is formed on the upper portion of the ridge stripe region 350 and the first stripe-side region 351, and the first and second stripe-side regions 351, 352 are both etched by dry etching method so that the second upper cladding layer 310 slightly remains. Then, with a wet etchant (phosphoric acid or hydrochloric acid), etching is continued to the first etching stop layer 309.

The buried layer 315 is formed on the entire surface, and the buried layer 315 on the ridge stripe region 350 other than the window regions 331, 332 is removed, and after the electrodes 320, 321 are formed, a wafer is cleaved to obtain the light emitting end surfaces 355, 356, each on which the reflection coatings 357, 358 are formed. It is to be noted that the buried layer 315 is formed on the p-type GaAs cap layer 314 in the window regions 331, 332 (unshown), which prevents non-effective current from flowing in the window region.

In the present embodiment, two etching stop layers 309, 311 are used to perform strict control over both the thickness H₁ and H₂ of the upper cladding layer on the region 351 and the region 352. This reduces dispersion of the horizontal beam divergence θh, and makes it possible to minimize the percentage of elements which generate kink.

In the present embodiment, as in the second embodiment, it is possible to adopt a manufacturing method for forming the second ridge-side region by utilizing that the etching stop effect of the second etching stop layer is weakened by layer intermixing in the window portion. Unlike the second embodiment, the first etching stop layer is available, which enables dispersion of the horizontal beam divergence θh to be decreased.

In the above embodiment, although each of the stop layers consisted of a single strained layer to suppress light absorption, they may be composed of a plurality of layers formed from quantum wells and barrier layers. In such a case, the strain may be weakened or completely eliminated. Moreover, although the etching stop layer, the first etching stop layer and the second etching stop layer were made of GaInP not containing Al, they may be made of AlGaInP containing Al, and in such a case, the strain may be weakened.

Although a plurality of quantum well layers were included in the active layer in the above embodiments, the quantum well layer may be a single layer.

Further, although the guide layer and the barrier layer shared the same Al composition of the above embodiments, the guide layer and the barrier layer may be different in the Al composition.

Furthermore, in the above embodiments, Si or Se may be used as a dopant for the n-type first cladding layer and the n-type second cladding layer.

Further, in the above embodiment, Be, Mg, Zn or the like may be used as a dopant for the p-type first cladding layer, the p-type first cladding layer and the p-type GaAs cap layer. Generally, MBE (Molecular Beam Epitaxy) method is applied to the case of using Be, and MOCVD (Metalorganic Chemical Vapor Deposition) method is applied to the case of using Mg or Zn to form each compound semiconductor layer.

In the above embodiments, as the buried layer, a semiconductor current blocking layer such as layers having an n-type GaAs disposed on an n-type AlInP, an n-type GaAs or an n-type AlInP may be formed instead of a dielectric film such as silicon oxides and silicon nitrides, so that difference in coefficient of thermal expansion can be decreased to reduce characteristic deterioration caused by heat treatment during processing. Moreover, it is possible to adopt the structure in which the buried layer is eliminated and an electrode is directly formed on the etching stop layer or the upper cladding layer. In this case, the electrode is considered to function also as the buried layer.

Further in the embodiments, as a window formation method, there was used so-called IILD (Impurity Induced Layer Disordering) method in which II-group atoms such as Zn are diffused so that the II-group atoms promote diffusion of Ga in GaAs and diffusion of Al, Ga or In in AlGaInP In this case, a diffusion source may include layers containing Zn except ZnO or layers containing Be, Mg, Cd and the like except Zn. As a window region formation method, it is possible to adopt IFVD (Impurity Free Vacancy Disordering) method in which a dielectric layer such as SiO₂ layers is formed on the window region to use diffusion of vacancy of V-group atoms (e.g., As, P) during heating operation.

Although semiconductor layers expressed by general equations of AlGaInP or GaInP were used as the lower cladding layer, the active layer and the upper cladding layer in the embodiments, semiconductor layers expressed by general equations of AlGaAs or GaAs may also be used.

Further, although semiconductor layers expressed by general equations of AlGaInP or GaInP were used as the lower cladding layer, the active layer and the upper cladding layer in the present invention, semiconductor layers expressed by general equations of AlGaInN and GaN may also be used.

Further, although semiconductor layers expressed by general equations of AlGaInP or GaInP were used as the lower cladding layer, the active layer and the upper cladding layer in the embodiments, semiconductor layers expressed by general equations of AlGaAs or InGaAs may also be used.

Furthermore, the embodiments disclosed in the present invention are to be considered in all respects as illustrative and not restrictive. The scope of the invention is indicated by the appended claims rather than by the forgoing description and all changes which come within the meaning and range of equivalency of the claims are therefore intended to be embraced therein.

Although the present invention has been fully described in conjunction with preferred embodiments thereof with reference to the accompanying drawings, various changes and modifications are possible for those skilled in the art. Therefore, such changes and modifications should be construed as included in the present invention unless they depart from the intention and scope of the invention as defined by the appended claims.

1. A semiconductor laser, comprising:
a ridge stripe region having a laminated structure provided with at least a lower cladding layer, an active layer, and an upper cladding layer, and formed on a semiconductor substrate;
a first stripe-side region disposed on both outer sides of the ridge stripe region, provide with a buried layer on the upper cladding layer, having a first thickness from a lower surface of the upper cladding layer to a lower surface of the buried layer, and having a width larger in a middle portion of an oscillator than in a light emitting edge; and
a second stripe-side region disposed on both outer sides of the first stripe-side region at least in a vicinity of the light emitting edge, provided with a buried layer on the upper cladding layer, and having a second thickness from the lower surface of the upper cladding layer to the lower surface of the buried layer, the second thickness being smaller than the first thickness.

2. The semiconductor laser according to claim 1, wherein a width of the first stripe-side region on the light emitting edge is equal to or more than 0.1 μm and equal to or less than 5 μm.

3. The semiconductor laser according to claim 1, wherein the active layer includes a quantum well, and crystals of the active layer are intermixed in the vicinity of the light emitting edge to form a window region.

4. The semiconductor laser according to claim 1, wherein the lower cladding layer, the active layer, and the upper cladding layer are formed from (AlₓGa₁₋ₓ)_{y}In_{1-y}P (0≦x≦1, 0≦y≦1).

5. The semiconductor laser according to claim 1, wherein the upper cladding layer of the laminated structure has first and second cladding layers with an etching stop layer interposed therebetween,
wherein in the first stripe-side region in the middle portion of the oscillator, the second upper cladding layer has a thickness equal to or more than 0.003 μm, and
wherein in the second stripe-side region in the vicinity of the light emitting edge, the second upper cladding layer is completely removed.

6. The semiconductor laser according to claim 1, wherein the upper cladding layer of the laminated structure has first and second cladding layers with an etching stop layer interposed therebetween,
wherein in the first stripe-side region in the middle portion of the oscillator, the second upper cladding layer is removed up to the etching stop layer, and
wherein in the second stripe-side region in the vicinity of the light emitting edge, the etching stop layer and part or all of the first upper cladding layer are removed.

7. The semiconductor laser according to claim 6, wherein the active layer includes a quantum well,
wherein crystals of the active layer and the etching stop layers are intermixed in the vicinity of the light emitting edge to form a window region, and
wherein in the second stripe-side region, the etching stop layer formed from intermixed crystals in the window region is removed.

8. The semiconductor laser according to claim 1, wherein the upper cladding layer of the laminated structure has first, second, and third upper cladding layers with first and second etching stop layers interposed therebetween,
wherein in the first stripe-side region in the middle portion of the oscillator, the third upper cladding layer is removed up to the second etching stop layer, and
wherein in the second stripe-side region in the vicinity of the light emitting edge, the third upper cladding layer, the second etching stop layer, and the second upper cladding layer are removed.

9. The semiconductor laser as defined in claim 8, wherein the active layer includes a quantum well,
wherein crystals of the active layer, the first etching stop layer, and the second etching stop layer are intermixed in the vicinity of the light emitting edge to form a window region, and
wherein in the second stripe-side region, the second etching stop layer formed from intermixed crystals in the window region is removed.

10. The semiconductor laser according to claim 8, wherein the active layer includes a quantum well,
wherein crystals of the active layer, the first etching stop layer, and the second etching stop layer are intermixed in the vicinity of the light emitting edge to form a window region, and
wherein a thickness of the first etching stop layer is larger than that of the second etching stop layer.

11. A method for manufacturing the semiconductor laser according to claim 5, comprising:
forming the lower cladding layer, the active layer, the first upper cladding layer, the etching stop layer and the second upper cladding layer in this order on the semiconductor substrate to provide the laminated structure;
forming the first stripe-side region by etching the laminated structure on both outer sides of the stripe region so as to leave the second upper cladding layer with a thickness equal to or more than 0.003 μm; and
forming the second stripe-side region by etching the second upper cladding layer up to the etching stop layer in the vicinity of the light emitting end surface.

12. A method for manufacturing the semiconductor laser according to claim 6, comprising:
forming the lower cladding layer, a lower guide layer, the active layer, an upper guide layer, the first upper cladding layer, the etching stop layer, and the second upper cladding layer in this order on the semiconductor substrate to provide the laminated structure;
forming the first stripe-side region by etching the upper cladding layer of the laminated structure up to the etching stop layer on both outer sides of the stripe region; and
forming the second strip-side region by partially or completely etching the first upper cladding layer in the vicinity of the light emitting edge.

13. A method for manufacturing the semiconductor laser according to claim 8, comprising:
forming the lower cladding layer, a lower guide layer, the active layer, an upper guide layer, the first upper cladding layer, the first etching stop layer, the second upper cladding layer with a thickness equal to or more than 0.003 μm, the second etching stop layer, and the third upper cladding layer in this order on the semiconductor substrate to provide the laminated structure;
forming the first stripe-side region by etching the third upper cladding layer of the laminated structure up to the second etching stop layer on both outer sides of the stripe region; and
forming the second stripe-side region by etching the second upper cladding layer of the laminated structure up to the first etching stop layer in the vicinity of the light emitting edge.
